(19) United States
(12) Patent Application Publication
(10) Pub. No.: US 2025/0255146 A1
(43) Pub. Date: Aug. 7, 2025

(54) DISPLAY PANEL AND DISPLAY MOTHERBOARD

(71) Applicants: Chengdu BOE Optoelectronics Technology Co., Ltd., Chengdu, Sichuan (CN); BOE Technology Group Co., Ltd., Beijing (CN)

(72) Inventors: Yanwei LU, Beijing (CN); Shengsen WANG, Beijing (CN); Yudiao CHENG, Beijing (CN)

(73) Assignees: Chengdu BOE Optoelectronics Technology Co., Ltd., Chengdu, Sichuan (CN); BOE Technology Group Co., Ltd., Beijing (CN)

(21) Appl. No.: 18/853,138

(22) PCT Filed: Feb. 18, 2024
(86) PCT No.: PCT/CN2024/077458

§ 371 Date: Oct. 1, 2024

(30) Foreign Application Priority Data
Feb. 27, 2023 (CN) 202310194751.0

(51) Int. Cl. H10K 59/80

(52) U.S. Cl. CPC H10K 59/8723

(57) ABSTRACT

A display panel includes: a display substrate, including a display region and a peripheral region; a plurality of light-emitting elements arranged on the surface of one side of the display region of the display substrate; a packaging cover plate arranged on the side of the light-emitting elements away from the display substrate; and supporting columns arranged between the display substrate and the packaging cover plate and distributed at gaps of the plurality of light-emitting elements, where the orthographic projection of each supporting column on a plane where the display substrate is located includes a main body region and a plurality of branch regions connected to end portions of the main body region, the main body area is located between adjacent light-emitting elements, and an included angle is formed between the extension direction of each branch region and the extension direction of the main body region.

### CROSS-REFERENCE TO RELATED APPLICATION

The present application claims priority to Chinese Patent Application No. 202310194751.0, filed on Feb. 27, 2023 and entitled “DISPLAY PANEL, DISPLAY MOTHERBOARD AND DISPLAY APPARATUS”, the entire content of which is incorporated herein by reference.

### TECHNICAL FIELD

The present disclosure belongs to the field of display technologies, and particularly relates to a display panel and a display motherboard.

### BACKGROUND OF THE INVENTION

This section is intended to provide background or context for embodiments set forth in claims. The descriptions herein are not admitted to be prior art just since they are included in this section.

Organic light-emitting diode display panels and quantum dot light-emitting diode display panels are often packaged by a packaging structure. The packaging structure is disposed outside a display region (AA region) and surrounds the display region to prevent water vapor from entering the display panel.

### SUMMARY OF THE INVENTION

The present disclosure provides a display panel, a display motherboard and a display apparatus.

In one aspect, an embodiment of the present disclosure provides a display panel including: a display substrate including a display region and a peripheral region;

a plurality of light-emitting elements disposed on a surface of one side of a display region of the display substrate;

a packaging cover plate disposed on one side of the plurality of light-emitting elements away from the display substrate;

a plurality of support pillars disposed between the display substrate and the packaging cover plate, where orthographic projections of the plurality of support pillars on the display substrate are disposed at gaps of orthographic projections of the plurality of light-emitting elements on the display substrate, an orthographic projection of each of the support pillars on the display substrate includes a main body region and a plurality of branch regions connected with end parts of the main body region, the main body region and the plurality of branch regions are all disposed between adjacent light-emitting elements in the plurality of light-emitting elements, and there is an included angle greater than 0° and less than 180° between an extension direction of each of the plurality of branch regions and an extension direction of the main body region.

Optionally, the plurality of light-emitting elements are arranged in a plurality of rows in a first direction, the plurality of light-emitting elements are arranged in a plurality of columns in a second direction, the first direction and the second direction are two directions parallel to a plane where the display substrate is disposed and the first direction and the second direction intersect with each other; and

the main body region is a strip-shaped region extending in the second direction.

Optionally, two light-emitting elements adjacent to one of the plurality of branch regions have at least one pair of parallel boundaries, the branch region is disposed between the pair of parallel boundaries, and an extension direction of the branch region is the same as an extension direction of the pair of parallel boundaries.

Optionally, the plurality of support pillars in two adjacent rows of light-emitting elements are arranged in a staggered manner in the second direction.

Optionally, at least part of light-emitting elements in the plurality of light-emitting elements are adjacent to the plurality of support pillars in the first direction, boundaries of the at least part of light-emitting elements are polygons, and the polygons include edges opposite the main body regions of the plurality of support pillars and edges opposite the branch regions of the plurality of support pillars; and

at least part of light-emitting elements in the plurality of light-emitting elements are adjacent to the plurality of support pillars in the second direction, boundaries of the part of light-emitting elements are polygons, and the polygons include edges opposite the branch regions of adjacent support pillars.

Optionally, the plurality of support pillars are distributed in alternate rows in the second direction, and the plurality of support pillars are arranged in a plurality of columns in the second direction;

one single light-emitting element is disposed between two adjacent support pillars in the first direction, a boundary of the single light-emitting element is a polygon, and the polygon includes edges opposite the branch regions of the two adjacent support pillars; and

one single light-emitting element is disposed between two adjacent support pillars in the second direction, and a boundary of the single light-emitting element includes edges opposite the branch regions of the two adjacent support pillars.

Optionally, each of the plurality of branch regions is polygonal or smooth curved.

Optionally, the display panel further includes a packaging structure, where the packaging structure is disposed between the display substrate and the packaging cover plate, is disposed on a surface of one side of the peripheral region, and surrounds the plurality of light-emitting elements; and

auxiliary support pillars, where the auxiliary support pillars are disposed between the display substrate and the packaging cover plate, and are disposed between a region where the plurality of light-emitting elements are disposed and the region where the packaging structure is disposed.

Optionally, the display substrate includes a gate electrode driving circuit disposed in the peripheral region, and at least part of the auxiliary support pillars are disposed in a region where the gate electrode driving circuit of the display substrate is disposed.

Optionally, the display panel further includes a packaging structure, and the packaging structure is disposed between the display substrate and the packaging cover plate, is disposed on the surface of one side of the peripheral region and surrounds the plurality of light-emitting elements;

a segment of the display substrate covered by the packaging structure includes a base, a conductive layer and an insulating layer which are sequentially laminated in a third direction, and the third direction is a direction where the display substrate points to the packaging cover plate; and

the conductive layer has a plurality of first openings, the insulating layer fills each of the plurality of first openings, the insulating layer has at least one second opening in a region where the plurality of first openings are disposed, there is a gap between the at least one second opening and an edge of the first opening where the at least one second opening is disposed, and the packaging structure fills the at least one second opening.

Optionally, a plurality of packaging openings of the display substrate in a packaging region include packaging openings in at least one shape of a first polygon, a second polygon and a closed smooth curve shape, the packaging openings include the plurality of first openings and the at least one second opening, the first polygon is a polygon with obtuse vertex angles and the second polygon is a polygon with rounded vertex angles.

Optionally, the display panel further includes a packaging structure, and the packaging structure is disposed between the display substrate and the packaging cover plate, is disposed on the surface of one side of the peripheral region and surrounds the plurality of light-emitting elements;

the surface of one side of the display substrate facing the packaging cover plate has a plurality of grooves in a coverage region of the packaging structure, and the packaging structure fills the plurality of grooves; and

the plurality of grooves include grooves in at least one shape of a first polygon, a second polygon and a closed smooth curve shape, the first polygon is a polygon with obtuse vertex angles, and the second polygon is a polygon with rounded vertex angles.

Optionally, a material of the grooves includes an insulating material;

the display substrate further includes the conductive layer with a plurality of opening regions, the display panel further includes an insulating layer, the insulating layer fills the opening regions of the conductive layer, the grooves are aggregated into a plurality of groove clusters, the plurality of groove clusters are in a one-to-one correspondence with the plurality of opening regions in the conductive layer, and grooves in the groove clusters are disposed in corresponding opening regions of the conductive layer; and

the plurality of opening regions include opening regions in at least one shape of a first polygon, a second polygon and a closed smooth curve shape, the first polygon is a polygon with obtuse vertex angles, and the second polygon is a polygon with rounded vertex angles.

In another aspect, an embodiment of the present disclosure provides a display panel including:

a display substrate including a display region and a peripheral region;

a plurality of light-emitting elements disposed on a surface of one side of a display region of the display substrate, where the plurality of light-emitting elements are arranged in a plurality of rows in a first direction, the plurality of light-emitting elements are arranged in a plurality of columns in a second direction, the first direction and the second direction are two directions parallel to the plane where the display substrate is disposed and the first direction and the second direction intersect with each other;

where the plurality of columns of light-emitting elements are divided into first light-emitting element columns and second light-emitting element columns, which are alternately arranged in the first direction, a number of the plurality of light-emitting elements in each first light-emitting element column is equal, a number of the plurality of light-emitting elements in each second light-emitting element column is equal, the number of the plurality of light-emitting elements in the first light-emitting element column is twice the number of the plurality of light-emitting elements in the second light-emitting element column, and the plurality of light-emitting elements in the first light-emitting element column and the plurality of light-emitting elements in the second light-emitting element column are arranged in a staggered manner in the second direction;

a packaging cover plate disposed on one side of the plurality of light-emitting elements away from the display substrate; and

a plurality of support pillars, where the plurality of support pillars are disposed between the display substrate and the packaging cover plate, and the plurality of support pillars and the plurality of light-emitting elements in the second light-emitting element columns are alternately arranged in the second direction.

Optionally, a boundary of each of the plurality of light-emitting elements in the second light-emitting element column is a rectangle with at least part of a region of a long edge on one side being recessed, and long edges of the rectangle extend in the second direction; and

an opening area of each of the plurality of light-emitting elements in the second light-emitting element column is greater than an opening area of each of the plurality of light-emitting elements in the first light-emitting element column.

Optionally, the display panel further includes: a packaging structure disposed on a surface of one side of the peripheral region of the display substrate, where the packaging structure is disposed between the display substrate and the packaging cover plate, and surrounds the plurality of light-emitting elements; and auxiliary support pillars disposed between the display substrate and the packaging cover plate, are disposed between a region where the plurality of light-emitting elements are disposed and a region where the packaging structure is disposed.

Optionally, the display panel further includes a packaging structure, and the packaging structure is disposed between the display substrate and the packaging cover plate, is disposed on the surface of one side of the peripheral region, and surrounds the plurality of light-emitting elements;

a segment of the display substrate covered by the packaging structure includes a base, a conductive layer and an insulating layer which are sequentially laminated in a third direction, and the third direction is a direction where the display substrate points to the packaging cover plate; and

the conductive layer has a plurality of first openings, the insulating layer fills each of the plurality of first openings, the insulating layer has at least one second opening in a region where the plurality of first openings are disposed, there is a gap between the at least one second opening and an edge of the first opening where the at least one second opening is disposed, and the packaging structure fills the at least one second opening; a plurality of packaging openings of the display substrate in a packaging region include the packaging openings in at least one shape of a first polygon, a second polygon and a closed smooth curve shape, the packaging openings include the plurality of first openings and the at least one second opening, the first polygon is a polygon with obtuse vertex angles, and the second polygon is a polygon with rounded vertex angles.

Optionally, the display panel further includes a packaging structure, and the packaging structure is disposed between the display substrate and the packaging cover plate, is disposed on the surface of one side of the peripheral region and surrounds the plurality of light-emitting elements; and

the surface of one side of the display substrate facing the packaging cover plate has a plurality of grooves in a coverage region of the packaging structure, and the packaging structure fills the plurality of grooves; the plurality of grooves include grooves in at least one shape of a first polygon, a second polygon and a closed smooth curve shape, the first polygon is a polygon with obtuse vertex angles, and the second polygon is a polygon with rounded vertex angles.

In another aspect, a display motherboard is provided and includes:

a plurality of display panels, where the display panel includes a display substrate including a display region and a peripheral region, a plurality of light-emitting elements disposed on the surface of one side of a display region of the display substrate, a packaging cover plate disposed on one side of the plurality of light-emitting elements away from the display substrate, and a packaging structure disposed on a surface of one side of the peripheral region of the display substrate, where the packaging structure is disposed between the display substrate and the packaging cover plate and surrounds the plurality of light-emitting elements; and

dummy support pillars disposed outside an outer boundary of the display panel, where a distance between orthographic projections of the plurality of dummy support pillars on a plane where the display motherboard is disposed and an orthographic projection of the display panel on the plane where the display motherboard is disposed is greater than 600 microns.

Optionally, a cross section of each of the plurality of dummy support pillars is circular; and/or,

the outer boundary of the display panel includes a smooth curve segment, the plurality of dummy support pillars are arranged in rows and columns, and a central connecting line of the plurality of dummy support pillars facing one side of the smooth curve segment of the display panel is stepped.

The present disclosure adopts the following technical solution: a display apparatus including the aforementioned display panel or including a display panel cut from the aforementioned display motherboard.

### BRIEF DESCRIPTION OF DRAWINGS

FIG. 1 is a cross-sectional view of a display panel according to an embodiment of the present disclosure:

FIG. 2 is an orthographic projection view of a partial structure of a display panel according to an embodiment of the present disclosure;

FIG. 3 is an orthographic projection view of a partial structure of a display panel in an embodiment of the present disclosure;

FIG. 4 is an orthographic projection view of a partial structure of a display panel in another embodiment of the present disclosure;

FIG. 5 is a partial engineering drawing of a display motherboard according to an embodiment of the present disclosure;

FIG. 6 is a partial schematic structural diagram of a display motherboard according to an embodiment of the present disclosure;

FIG. 7 is a structural diagram of a display apparatus according to an embodiment of the present disclosure;

FIG. 8 is an orthographic projection view of a partial structure of a display panel in another embodiment of the present disclosure;

FIG. 9 is an enlarged partial detail view of the orthographic projection view shown in FIG. 8;

FIG. 10 is a partial layout of a display substrate according to an embodiment of the present disclosure:

FIG. 11 is a partial layout of a display substrate according to another embodiment of the present disclosure;

FIG. 12 is a partial layout of a display substrate according to another embodiment of the present disclosure;

FIG. 13 is a cross-sectional view of a display substrate according to an embodiment of the present disclosure; and

FIG. 14 is an overall structural diagram of a display substrate according to an embodiment of the present disclosure.

### DETAILED DESCRIPTION

The present disclosure will be further explained in combination with the embodiments shown in the accompanying drawings.

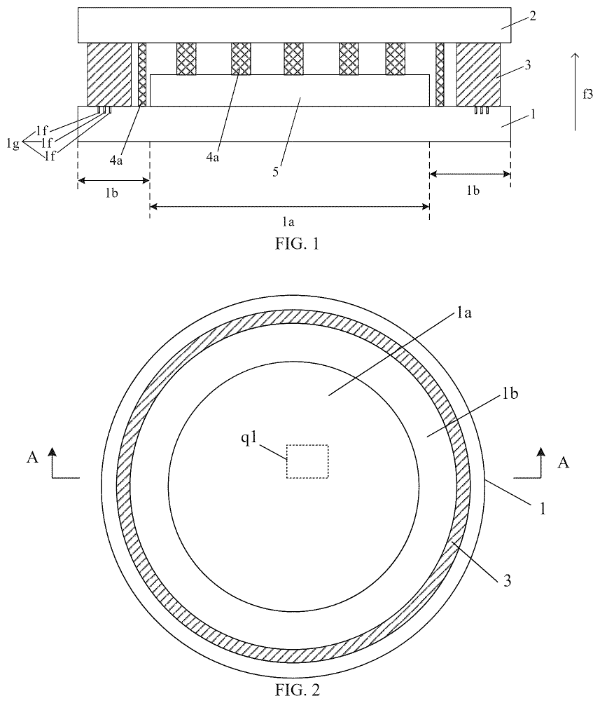

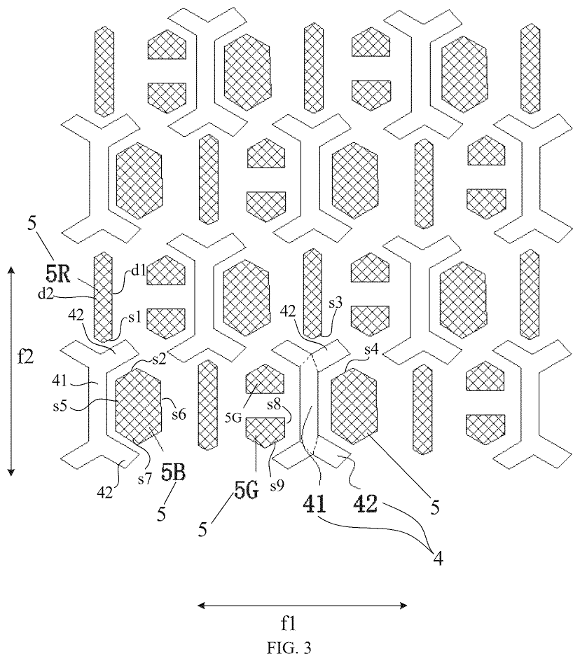

FIG. 1 is a cross-sectional view of a display panel according to an embodiment of the present disclosure (the cross-sectional view may be taken at position of A-A in FIG. 2). FIG. 2 is an orthographic projection view of a partial structure of a display panel according to an embodiment of the present disclosure. FIG. 3 is an orthographic projection view of a partial structure of a display panel in an embodiment of the present disclosure (FIG. 3 may be a schematic diagram of a region q1 in FIG. 2).

Referring to FIG. 1 to FIG. 3, a display panel according to an embodiment of the present disclosure includes:

a display substrate 1 including a display region 1a and a peripheral region 1b;

a plurality of light-emitting elements disposed on a surface of one side of the display region la of the display substrate 1 (the light-emitting elements are not individually labeled in FIG. 1, for example, the light-emitting elements may be arranged into a light-emitting element array 5); and

a packaging cover plate 2 disposed on one side of the light-emitting elements away from the display substrate.

Referring to FIG. 3 and FIG. 1, in some embodiments of the present disclosure, the display panel further includes a plurality of support pillars 4, the support pillars 4 are disposed between the display substrate 1 and the packaging cover plate 2, and orthographic projections of the support pillars 4 on the display substrate 1 are disposed at gaps of orthographic projections of the plurality of light-emitting elements on the plane where the display substrate 1 is disposed. Each of the orthographic projections of the support pillar 4 on the plane where the display substrate 1 is disposed includes a main body region 41 and a plurality of branch regions 42 connected with end parts of the main body region 41. Both the main body region 41 and the branch regions 42 are disposed between adjacent light-emitting elements, and there is an included angle greater than 0° and less than 180° between an extension direction of the branch region 42 and an extension direction of the main body region 41 (that is, the extension direction of the branch region 42 is different from the extension direction of the main body region 41). Alternatively, it may be considered that any branch region 42 is disposed between adjacent boundaries of two adjacent light-emitting elements.

In summary, in the display panel according to the embodiment of the present disclosure, the plurality of support pillars are disposed between the display substrate and the packaging cover plate, the orthographic projection of the support pillar on the plane where the display substrate is disposed includes the main body region and the plurality of branch regions connected with the end parts of the main body region, both the main body region and the branch regions are disposed between adjacent light-emitting elements, and the extension direction of the branch region is different from the extension direction of the main body region, so that cross-sectional areas of the support pillars are increased by disposing the support pillars whose orthographic projections include the branch regions extending in other directions, thereby improving a supporting effect of the support pillars for the packaging cover plate.

In addition, the flatness of different regions of the packaging cover plate can be improved after the supporting effect of the support pillars for the packaging cover plate is improved, so that the Newton ring problem can be improved

In an exemplary embodiment, please refer to FIG. 1 and FIG. 2. The display panel further includes a packaging structure 3. The packaging structure 3 is disposed between the display substrate 1 and the packaging cover plate 2, disposed on the surface of one side of the peripheral region 1b of the display substrate 1, and surrounds the plurality of light-emitting elements.

The plurality of light-emitting elements are disposed on the display region 1a (also called AA region) of the display substrate 1. The shape and arrangement of the light-emitting elements are not particularly limited in the present disclosure.

The peripheral region 1b of the display substrate 1 surrounds the display region 1a. For example, a gate on array (GOA) may be disposed in the peripheral region 1b of the display substrate 1.

The packaging structure 3 is disposed in the peripheral region 1b. The packaging structure 3 is closely bonded to the packaging cover plate 2 and the display substrate 1. The packaging structure 3 may support the packaging cover plate 2 on one hand, and may prevent water vapor from entering the display panel on the other hand.

In an exemplary embodiment, the display substrate 1 and the packaging cover plate 2 are both rigid structures. Optionally, a material of the packaging cover plate 2 includes glass. In some embodiments, the packaging cover plate 2 may have some functional circuits (such as touch control circuits) therein. In some other embodiments, no functional circuits are disposed on the packaging cover plate 2.

The light-emitting element may be various types of light-emitting elements, for example, the light-emitting element may include an organic light-emitting diode, or the light-emitting element may include a quantum dot light-emitting diode. In some embodiments, the packaging structure 3 is obtained by processing frit. Materials of the frit include glass frit and an organic solvent. The glass frit is, for example, borosilicate glass.

In an exemplary embodiment, when preparing the display panel according to the embodiment of the present disclosure, the frit is coated on a packaging region of the display substrate 1, and the organic solvent therein is removed by heating the frit. Subsequently, the display substrate 1 and the packaging cover plate 2 are bonded, and the frit from which the organic solvent is removed is irradiated by laser, so as to form a sealed space between the display substrate 1 and the packaging cover plate 2.

In some embodiments, please refer to FIG. 3, a plurality of light-emitting elements 5 are arranged in a plurality of rows in a first direction f1, and a plurality of light-emitting elements are arranged in a plurality of columns in a second direction f2. The first direction f1 and the second direction f2 are two directions that are parallel to the plane where the display substrate is disposed and intersect with each other.

The main body region 41 is a strip-shaped region extending in the second direction f2. The main body region 41 in such a shape can improve a utilization ratio of the support pillar 4 for the space between two adjacent light-emitting elements 5 in the first direction f1, thereby improving the supporting effect of the support pillar 4 for the packaging cover plate.

In some embodiments, please refer to FIG. 3, two adjacent light-emitting elements 5 have at least one pair of adjacent parallel boundaries, and the branch region 42 is disposed between the parallel boundaries (for example, a pair of parallel boundaries s1 and s2 and another pair of parallel boundaries s3 and s4 in FIG. 3) and the extension direction of the branch region 42 is the same as the extension direction of the pair of parallel boundaries (for example, s1 and s2). The extension direction of the branch region 42 is the same as the extension direction of the parallel boundaries of the light-emitting elements, which can improve the utilization ratio of the support pillar 4 for the space between the parallel boundaries of the light-emitting elements, thereby improving the supporting effect of the support pillar 4 for the packaging cover plate.

It should be noted that in the embodiment of the present disclosure, the extension direction of the branch region 42 being the same as the extension direction of the parallel boundaries of the two adjacent light-emitting elements includes: the extension direction of the branch region 42 is absolutely the same as the extension direction of the parallel boundaries of the two adjacent light-emitting elements, and an included angle between the extension direction of the branch region 42 and the extension direction of the parallel boundaries of the light-emitting elements is within plus or minus 5°.

In some embodiments, in combination with FIG. 3, the support pillars 4 (including the main body regions 41 and the branch regions 42) in the same row of light-emitting elements are arranged periodically, the interval between the support pillars 4 in any two rows of light-emitting elements is equal, and the support pillars 4 in two adjacent rows of light-emitting elements are arranged in a staggered manner in the second direction f2. The staggered arrangement here may mean that the support pillars 4 in two adjacent rows do not directly face each other in the second direction f2.

Since the support pillars 4 have the branch regions 42, the staggered arrangement of the support pillars 4 in two adjacent rows of light-emitting elements in the second direction f2 can effectively avoid structural interference between the support pillars 4. Furthermore, the distance between the light-emitting elements in two adjacent rows can be smaller, so that it is convenient to improve a density of the light-emitting elements in the display panel, and thus to improve a display effect of the display panel.

In some embodiments, with continued reference to FIG. 3, in the plurality of light-emitting elements (for example, 5R, 5B and 5G) in the display panel, at least part of light-emitting elements are adjacent to the support pillars 4 in the first direction f1, the boundaries of the at least part of light-emitting elements are polygons, and the polygons include edges opposite the main body regions 41 of the support pillars 4 and edges opposite the branch regions 42 of the support pillars 4.

In FIG. 3, the boundary of the blue light-emitting element 5B is a hexagon, the hexagon has a group of opposite edges (s5 and s6) extending in the second direction f2, where one edge (s5) is opposite the main body region 41 of the support pillar 4. The hexagon also has four edges of which the extension directions intersect with both the first direction f1 and the second direction f2, where two edges (s2 and s7) are opposite the branch regions 42 of the support pillar 4.

In FIG. 3, every two green light-emitting elements 5G form a pair, luminance of a pair of green light-emitting elements 5G may be kept equal at all times, and the pair of green light-emitting elements 5G form one sub-pixel. The boundary of each green light-emitting element 5G is a pentagon. The pentagon has an edge s8 extending in the second direction f2 and is opposite the main body region 41 of the support pillar 4, and also has an edge s9 opposite the branch region 42 of the support pillar 4.

Similarly, in some embodiments, referring to FIG. 3, at least part of light-emitting elements are adjacent to the support pillars 4 in the second direction f2, the boundaries of the part of light-emitting elements are polygons, and the polygons include edges opposite the branch regions of adjacent support pillars 4.

The boundary of the red light-emitting element 5R in FIG. 3 is a hexagon. The hexagon has a group of opposite edges dl and d2 extending in the second direction f2. The hexagon also has four edges extending in the direction intersecting with the first direction f1 and the second direction f2, and each of the four edges is opposite one branch region 42 (that is, the four edges are opposite four branch regions 42 one to one).

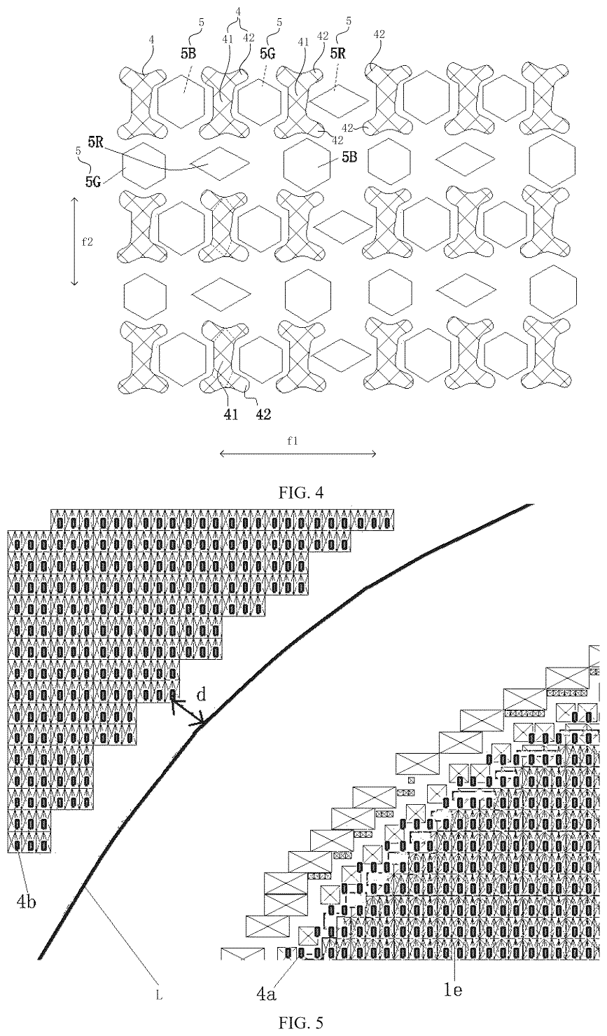

In some embodiments, in combination with FIG. 4, the support pillars 4 are distributed in alternate rows in the second direction f2, and the support pillars 4 are arranged in a plurality of columns in the second direction f2.

For example, in the odd rows shown in FIG. 4, the support pillars 4 and the light-emitting elements 5 are alternately disposed, and in the even rows, the support pillars 4 are vacant. The area occupied by the support pillars 4 in the odd rows is large enough, and since the support pillars 4 have the branch regions 42, a total supporting area of the support pillars 4 may be set large enough. The vacant arrangement of the support pillars 4 in the even rows can avoid the structural interference between the support pillars 4.

For another example, in the even rows, the support pillars 4 and the light-emitting elements are alternately disposed, and in the odd rows, no support pillars 4 are disposed.

In some embodiments, a single light-emitting element (such as 5R, 5B and 5G in FIG. 4) is disposed between two adjacent support pillars 4 in the first direction f1, the boundary of the single light-emitting element is a polygon, and the polygon includes edges opposite the branch regions 42 of the two support pillars 4.

In some embodiments, a single light-emitting element is disposed between two adjacent support pillars 4 in the second direction, and the boundary of the single light-emitting element includes edges opposite the branch regions of the two support pillars 4.

Optionally, in the embodiment shown in FIG. 4, the red light-emitting element 5R is rhombic as a whole, the blue light-emitting element 5B is hexagonal, and the green light-emitting element 5G is hexagonal, but various light-emitting elements may also be in other shapes, which is not limited by the embodiment of the present disclosure.

Each of four edges of the red light-emitting element 5R between two adjacent support pillars 4 in the first direction is opposite one branch region 42 (that is, four edges are opposite four branch regions 42 one to one). A group of opposite edges of the blue light-emitting element 5B between two adjacent support pillars 4 in the first direction f1 are respectively opposite the main body region 41 of one support pillar 4 (that is, the two opposite edges are opposite the two main body regions 41 one to one), and each of the rest four edges is opposite one branch region 42 (that is, the four edges are opposite four branch regions 42 one to one). Each of a group of opposite edges of the green light-emitting element 5G between two adjacent support pillars 4 in the first direction f1 is opposite the main body region 41 of one support pillar 4 (that is, the two opposite edges are opposite the two main body regions 41 one to one), and each of the rest four edges is opposite one branch region 42.

The boundary of each light-emitting element between two adjacent support pillars 4 in the second direction f2 has the edge opposite the branch region 42, but does not have the edge opposite the main body region 41.

In some embodiments, referring to FIG. 3 and FIG. 4, the branch region 42 is polygonal or smooth curved, for example, the branch region 42 shown in FIG. 3 is polygonal and the branch region 42 shown in FIG. 4 is smooth curved.

FIG. 5 is a partial engineering drawing of a display motherboard according to an embodiment of the present disclosure. The display motherboard is used to cut out the display panel. Referring to FIG. 5 and in combination with with FIG. 1, in some embodiments, the display panel further includes auxiliary support pillars 4a, and the auxiliary support pillars 4a are disposed between the display substrate 1 and the packaging cover plate 2, and between the region where the plurality of light-emitting elements are disposed (this region may be the region where the light-emitting element array 5 is disposed) and the region where the packaging structure 3 is disposed.

The rectangular patterns of the auxiliary support pillars 4a in FIG. 5 only indicate positions of the auxiliary support pillars 4a, and a cross section of the auxiliary support pillar 4a is, for example, circular or rectangular or any other suitable shapes.

The cutting line L in FIG. 5 indicates the cutting position where the display panel will be cut out from the display motherboard. The display motherboard includes a plurality of display panels, and the display panels are, for example, distributed in a rectangular array. The partial boundary region of only one of the display panels is shown in FIG. 5.

In some embodiments, the display substrate 1 includes a gate electrode driving circuit le, and at least part of the auxiliary support pillars 4a are disposed on the region where the gate electrode driving circuit of the display substrate 1 is disposed. Optionally, the gate electrode driving circuit le is disposed in the peripheral region 1b of the display substrate 1 and on the inner side of the region where the packaging structure 3 is disposed (the inner side here may refer to one side of the packaging structure 3 close to the center of the display substrate 1).

The auxiliary support pillars 4a may further increase the supporting area for the packaging cover plate 2, which is favorable to improve the pass rate of a drop test of the whole display panel.

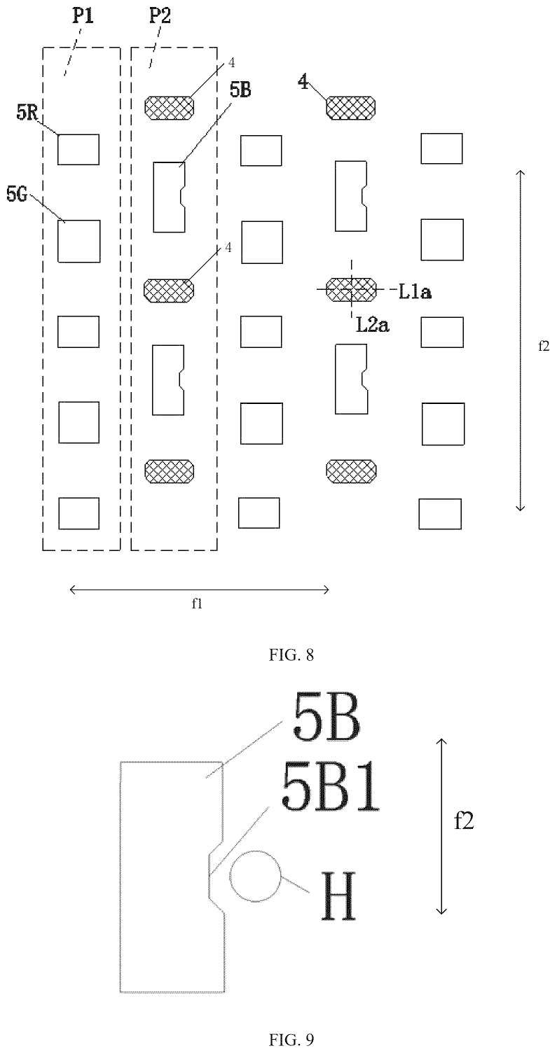

With continued reference to FIG. 8 and FIG. 9 and in combination with FIG. 1 and FIG. 2, some other embodiments of the present disclosure also provide a display panel including:

a display substrate 1 including a display region 1a and a peripheral region 1b;

a plurality of light-emitting elements (the plurality of light-emitting elements form a light-emitting element array 5 and include red light-emitting elements 5R, green light-emitting elements 5G and blue light-emitting elements 5B) disposed on the surface of one side of the display region la of the display substrate 1, where the plurality of light-emitting elements are arranged in a plurality of rows in a first direction f1, the plurality of light-emitting elements are arranged in a plurality of columns in a second direction f2, and the first direction f1 and the second direction f2 are two directions parallel to the plane where the display substrate 1 is disposed and intersect with each other;

the plurality of columns of light-emitting elements are divided into first light-emitting element columns P1 and second light-emitting element columns P2, which are alternately arranged in the first direction, the number of the light-emitting elements in each first light-emitting element column P1 is equal, the light-emitting elements in each first light-emitting element column PI may be arranged in an aligned manner in the second direction f2, the number of the light-emitting elements in each second light-emitting element column P2 is equal, the light-emitting elements in each second light-emitting element column P2 may be arranged in an aligned manner in the second direction f2, the number of the light-emitting elements in the first light-emitting element column P1 is twice the number of the light-emitting elements in the second light-emitting element column. and the light-emitting elements in the first light-emitting element column P1 and the light-emitting elements in the second light-emitting element column P2 are arranged in a staggered manner in the second direction f2;

a packaging cover plate 2 disposed on one side of the light-emitting elements away from the display substrate 1; and

a plurality of support pillars 4 disposed between the display substrate 1 and the packaging cover plate 2, where the support pillars 4 and the light-emitting elements in the second light-emitting element columns P2 are alternately arranged in the second direction, and the plurality of support pillars 4 may be arranged in an aligned manner in the first direction f1.

In the embodiment of the present disclosure, two structures on the display substrate 1 being arranged in an aligned manner in a set direction (such as the first direction f1 and the second direction f2) parallel to the plane where the display substrate 1 is disposed means that a distance between two straight lines, which pass through centers of orthographic projections of the two structures on the plane where the display substrate 1 is disposed and are parallel to the set direction. is less than half of the size of the orthographic projections of the two structures on the plane where the display substrate 1 is disposed in the direction perpendicular to the set direction. Ideally, the centers of the orthographic projections of the two structures on the plane where the display substrate 1 is disposed are disposed on the same straight line parallel to the set direction.

In the embodiment of the present disclosure, the two structures on the display substrate 1 being arranged in a staggered manner in the set direction parallel to the plane where the display substrate 1 is disposed means that the distance between two straight lines, which pass through the centers of the orthographic projections of the two structures on the plane where the display substrate 1 is disposed and are parallel to the set direction, is greater than half of the size of the orthographic projections of the two structures on the plane where the display substrate 1 is disposed in the direction perpendicular to the set direction. Ideally, the orthographic projections of the two structures on the plane where the display substrate 1 is disposed have no overlapping region in the set direction.

The light-emitting elements with smaller areas (for example, the red light-emitting elements 5R and the green light-emitting elements 5G in FIG. 8) may be disposed in the first light-emitting element column P1, and the light-emitting elements with larger areas (for example, the blue light-emitting elements 5B in FIG. 8) may be disposed in the second light-emitting element column P2. Taking the red, green and blue light-emitting elements disposed in the display panel as an example, since only half of the light-emitting elements need to be disposed in the second light-emitting element column P2 compared with the first light-emitting element column P1, the area in the second light-emitting element column P2 that can be used for disposing the support pillars 4 is large enough, so that the support pillars 4 can support the packaging cover plate 2 more stably.

In some embodiments, an opening area of the light-emitting element in the second light-emitting element column P2 is greater than an opening area of the light-emitting element in the first light-emitting element column P1.

The opening area of the light-emitting element refers to the area of a light emergent surface of the light-emitting element.

In some other embodiments, the opening area of the light-emitting element in the second light-emitting element column P2 is equal to the opening area of at least one light-emitting element in the first light-emitting element column P1.

In some embodiments, openings of the light-emitting elements in the first light-emitting element column P1 are rectangular.

Since the light-emitting elements in the first light-emitting element column PI are more and regularly arranged, the opening areas are greater than the opening areas of other shapes when the openings are rectangular.

In some other embodiments, the openings of the light-emitting elements in the first light-emitting element column P1 are in other shapes such as diamond, pentagon or hexagon.

In some embodiments, referring to FIG. 8 and FIG. 9, the opening of the light-emitting element in the second light-emitting element column P2 is in the shape of a rectangle with part of the region of the long edge on one side being recessed, and the long edges of the rectangle extend in the second direction f2.

In the embodiment shown in FIG. 9, the light-emitting elements in the second light-emitting element column P2 are the blue light-emitting elements 5B, each of the blue light-emitting elements 5B is in the shape of a rectangle as a whole, long edges on both sides of the rectangle extend in the second direction f2, a middle part of the long edge on one side of the rectangle is recessed and forms a recessed segment 5B1, and the recessed segment 5B1 is used to avoid a via hole H or other structures. The via hole His, for example, a via hole connecting a pixel circuit (not shown) and a light-emitting layer (not shown) in the display substrate, or a via hole freely connecting two layers of conductive structures.

Since the number of the light-emitting elements in the second light-emitting element column P2 is less than the number of the light-emitting elements in the first light-emitting element column P1, the opening area of the light-emitting element in the second light-emitting element column P2 may be set to be large enough, and a luminous quantity of the light-emitting element will not be affected by inward recessing of a certain edge for structural avoidance.

In some embodiments, referring to FIG. 8, the support pillar 4 has a long axis L1a extending in the first direction f1 and a short axis L2a extending in the second direction. In these embodiments, the orthographic projection of the support pillar 4 on the plane where the display panel is disposed has two symmetrical axes L1a and L2a perpendicular to each other, that is, the long axis L1a of the support pillar 4 is set to be parallel to the first direction f1 to avoid the light-emitting elements in the second direction, and more space is reserved for the light-emitting elements in the second direction f2, so that the areas of the light-emitting elements in the second light-emitting element column P2 can be set to be large enough.

In some other embodiments, if the area for disposing the support pillar 4 is large enough, the support pillar 4 has a long axis extending in the second direction f2 and a short axis extending in the first direction f1. The area of the support pillar 4 can be set relatively large.

Since the area in the second light-emitting element column P2 for disposing the support pillar 4 is relatively large, the orthographic projection of the support pillar 4 on the plane where the display panel is disposed is not limited to a polygon, but may also be, for example, a circle or an ellipse.

In some embodiments, referring to FIG. 8, the first light-emitting element column P1 includes the red light-emitting elements 5R and the green light-emitting elements 5G, which are alternately disposed in the second direction f2, and the second light-emitting element column P2 includes the blue light-emitting elements 5B.

Since the opening area of the blue light-emitting element 5B is the largest, the blue light-emitting element 5B is disposed in the second light-emitting element column P2.

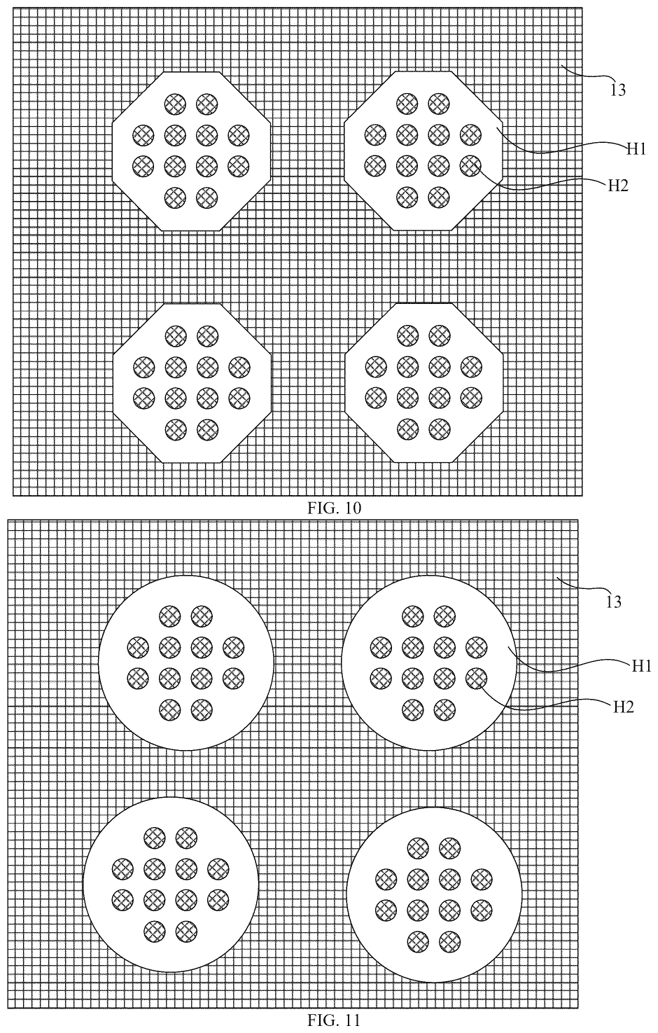

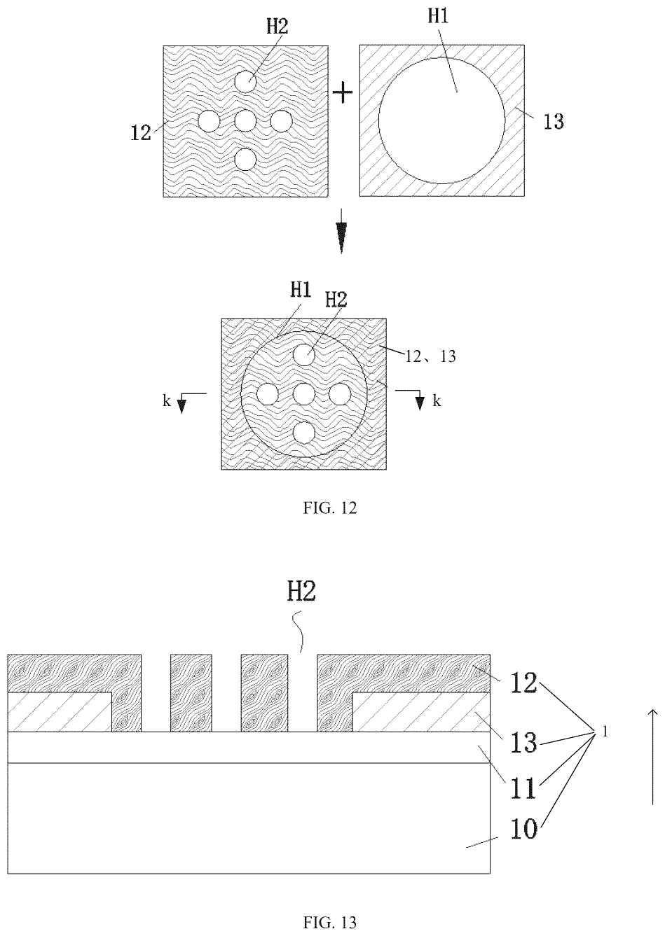

FIG. 13 may be a cross-sectional view of FIG. 12 at k-k. Referring to FIG. 10, FIG. 12 and FIG. 13 and in combination with with FIG. 1, in the display panel according to some other embodiments of the present disclosure, a segment of the display substrate 1 covered by the packaging structure 3 includes a base 10, a conductive layer 13 and an insulating layer 12 which are sequentially laminated in a third direction f3, and the third direction f3 is a direction where the display substrate 1 points to the packaging cover plate 2.

The conductive layer 13 bas a plurality of first openings H1, the insulating layer 12 fills each of the plurality of first openings H1, the insulating layer 12 is provided with at least one second opening H2 in the region where each of the plurality of first openings Hl is disposed, and there is a gap between the at least one second opening H2 and each of the plurality of first openings HI where the second opening H2 is disposed. It should be noted that, in order to clearly show the first openings HI and the second openings H2, the insulating layer 12 is not shown in FIG. 10 and FIG. 11, but the at least one second opening H2 in the insulating layer 12 is shown, which is not limited by the embodiment of the present disclosure.

The packaging structure 3 fills the second openings H2, so that a contact area between the packaging structure 3 and the display substrate 1 can be increased, and a bonding tightness between the packaging structure 3 and the display substrate 1 is further improved

At any position of the boundary of the orthographic projection of at least one first opening H1 on a plane which is parallel to a plane where the display substrate is disposed, an included angle between a left tangent and a right tangent is greater than 90°; and/or at any position of the boundary of the orthographic projection of at least one first opening H2 on a plane which is parallel to the plane where the display substrate is disposed, an included angle between the left tangent and the right tangent is greater than 90°, and the plane parallel to the plane, where the display substrate is disposed, is the plane where the display substrate is disposed.

Optionally, a plurality of packaging openings of the display substrate in a packaging region include packaging openings in at least one shape of a first polygon, a second polygon and a closed smooth curve shape. The packaging openings include the first openings H1 and the second openings H2, the first polygon is a polygon with obtuse vertex angles and the second polygon is a polygon with rounded vertex angles.

Under such a structure, there is no right angle or acute angle at the boundaries of the first openings H1 and the second openings H2, and the transition at the boundaries of the first opening H1 and the second opening H2 is relatively smooth, which is helpful to distribute the stress more dispersedly at the boundaries of the first opening H1 and the second opening H2, thereby reducing the risk of structural fracture at the first opening H1 or the second opening H2 and helping to improve structural stability of the display substrate.

Optionally, the display substrate 1 further includes a buffer layer 11, the buffer layer 11 is disposed on the base 10, and the conductive layer 13 is disposed on the buffer layer 11. The second openings H2 of the insulating layer 12 expose the buffer layer 11 on the base 10.

Optionally, a material of the buffer layer 11 may include an inorganic material, such as silicon oxide and silicon nitride, so as to achieve the effect of blocking water and oxygen and alkaline ions.

Optionally, the base 10 is a rigid base. For example, a material of the base 10 may be glass.

The display substrate 1 and the packaging cover plate 2 are both rigid structures. In some embodiments, the material of the packaging cover plate 2 is glass. In some embodiments, some functional circuits (such as touch control circuits) may also be disposed on the packaging cover plate 2. In some other embodiments, no functional circuits are disposed on the packaging cover plate 2.

The light-emitting element is, for example, an organic light-emitting diode or a quantum dot light-emitting diode. In some embodiments, the packaging structure 3 is obtained by processing frit Materials of the frit include glass frit and an organic solvent. The glass frit is, for example, borosilicate glass.

Referring to FIG. 10, at least one first opening HI is in the shape of a polygon, and the vertex angles of the polygon are all obtuse angles. At the vertex angles of the polygon, the included angle between the left tangent and the right tangent is an obtuse angle, and at the rest positions of the polygon, the included angle between the left tangent and the right tangent is 180°. The opening shape of the first opening H1 is, for example, a regular pentagon or a regular hexagon.

Referring to FIG. 11, the opening shape of at least one first opening H1 is a closed smooth curve. The smooth curve is differentiable everywhere, and the included angle between the left tangent and the right tangent at any position is 180°.

The closed smooth curve is, for example, a circle or an ellipse.

In some embodiments, the opening shape of at least one first opening Hl is a polygon with rounded angle tips. At the intersection of a rounded angle segment and a straight segment, the included angle between the left tangent and the right tangent is an obtuse angle.

Referring to FIG. 10, at least one second opening H2 is in the shape of a polygon, and the vertex angles of the polygon are all obtuse angles. At the vertex angles of the polygon, the included angle between the left tangent and the right tangent is an obtuse angle, and at the rest positions of the polygon, the included angle between the left tangent and the right tangent is 180°. The opening shape of the second opening H2 is, for example, a regular pentagon or a regular hexagon.

Referring to FIG. 11, the opening shape of at least one second opening H2 is a closed smooth curve. The smooth curve is differentiable everywhere, and the included angle between the left tangent and the right tangent at any position is 180°.

The closed smooth curve is, for example, a circle or an ellipse.

In some embodiments, the opening shape of at least one second opening H2 is a polygon with rounded angle tips. At the intersection of the rounded angle segment and the straight segment, the included angle between the left tangent and the right tangent is an obtuse angle.

The above opening shapes may be designed in combination. For example, in some other embodiments, the opening shape of the first opening H1 is a circle or an ellipse, and the shape of the second opening H2 may be in the shape of a rectangle, circle and regular octagon with rounded angle tips.

In the above design, respective tips of opening regions (the first openings H1) of the conductive layer 13 and opening regions (the second openings H2) of the insulating layer 12 are smoothly transitioned to avoid excessive stress concentration, thus improving reliability of the display apparatus.

In some embodiments shown in FIG. 11, a diameter of the first opening H1 is 35 microns (μm) to 45 μm, a diameter of the second opening H2 is 5 μm to 7 μm, and a gap size of the second openings H2 is 3 μm to 4 μm.

Optionally, in one embodiment shown in FIG. 11, the diameter of the first opening H1 is 40 μm, the diameter of the second opening H2 is 6 μm, and the gap size between adjacent second openings H2 is 3.5 μm.

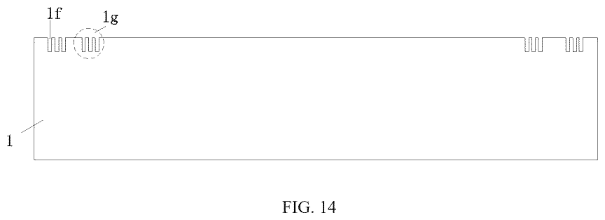

Based on the same inventive concept, with continued reference to FIG. 1 and FIG. 14, some embodiments of the present disclosure also provide a display panel, including a display substrate 1 and a packaging cover plate 2 which are disposed opposite each other, a plurality of light-emitting elements disposed on a surface of one side of the display substrate 1 facing the packaging cover plate 2, and a packaging structure 3 which is disposed between the display substrate 1 and the packaging cover plate 2 and surrounds the plurality of light-emitting elements.

The surface of one side of the display substrate 1 facing the packaging cover plate 2 has a plurality of grooves 1f in a coverage region of the packaging structure 3, and the packaging structure 3 fills the plurality of grooves 1f. In this way, the contact area between the packaging structure 3 and the display substrate 1 can be increased, and the bonding tightness between the packaging structure 3 and the display substrate 1 is further improved.

At any position of the boundary of the orthographic projection of at least one groove 1f on a plane which is parallel to the plane where the display substrate is disposed, the included angle between the left tangent line and the right tangent line is greater than 90°, and the plane parallel to the plane, where the display substrate is disposed, is the plane where the display substrate 1 is disposed.

Optionally, the plurality of grooves 1f include grooves in at least one shape of a first polygon, a second polygon and a closed smooth curve shape, the first polygon is a polygon with obtuse vertex angles, and the second polygon is a polygon with rounded vertex angles.

The opening shape of the groove 1f is the opening shape of the second opening H2 in the insulating layer 12. The corner position of the groove 1f is relatively smooth, and the stress at the corner position is relatively small during a whole drop test. At the same time, the corner position of the packaging structure 3 filling the grooves 1f is relatively smooth, and an internal stress of the packaging structure 3 is relatively small during the whole drop test. All these are helpful to improve the reliability of the display panel and the display apparatus formed by the display panel.

In some embodiments, an opening of at least one groove 1f is circular or elliptical.

In some embodiments, the surface of the groove 1f is formed by an insulating material. For example, side walls of some grooves 1f are formed by the insulating material disposed at the same layer as an interlayer dielectric layer (the interlayer dielectric layer is a film layer in the display panel) and the insulating material disposed at the same layer as a passivation layer (the passivation layer is a film layer in the display panel), and bottom walls of the grooves 1f are formed by the buffer layer.

In some embodiments, with continued reference to FIG. 1, FIG. 12 and FIG. 14, the display substrate 1 includes a conductive layer 13, and the conductive layer 13 has a plurality of opening regions. The insulating material fills the opening regions of the conductive layer 13, and the grooves extend into the opening regions of the conductive layer 13. The grooves 1f are clustered into a plurality of groove clusters 1g, the groove clusters 1g are disposed in one-to-one correspondence with the opening regions in the conductive layer 13, and the grooves 1f in the groove clusters 1g are disposed in the corresponding opening regions of the conductive layer 13.

The opening regions of the conductive layer 13 are the opening regions of the first openings H1. The tips of the opening regions of the conductive layer 13 are transitioned smoothly to avoid excessive stress concentration, thereby improving the reliability of the display apparatus.

In some embodiments, at any position of the boundary of the orthographic projection of at least one opening region on a plane which is parallel to the plane where the display substrate is disposed, the included angle between the left tangent and the right tangent is greater than 90°.

In some embodiments, the plurality of grooves 1f include the grooves in at least one shape of a first polygon, a second polygon and a closed smooth curve shape, the first polygon is a polygon with obtuse vertex angles and the second polygon is a polygon with rounded vertex angles.

In some embodiments, at least one opening region is in the shape of a closed smooth curve.

In some embodiments, at least one opening region is circular or elliptical.

In summary, in the display panel according to the embodiment of the present disclosure, the plurality of support pillars are disposed between the display substrate and the packaging cover plate, the orthographic projection of the support pillar on the plane where the display substrate is disposed includes the main body region and the plurality of branch regions connected with the end parts of the main body region, both the main body region and the branch regions are disposed between adjacent light-emitting elements, and the extension direction of the branch region is different from the extension direction of the main body region, so that cross-sectional areas of the support pillars are increased by disposing the support pillars whose orthographic projections include the branch regions extending in other directions, thereby improving the supporting effect of the support pillars for the packaging cover plate.

In addition, after improving the supporting effect of the support pillars for the packaging cover plate, the flatness of different regions of the packaging cover plate can be improved, so that the Newton ring problem can be improved.

Based on the same inventive concept, referring to FIG. 7, some embodiments of the present disclosure also provide a display apparatus including the preceding display panel.

The display apparatus is a product or component with a display function. The display apparatus is, for example, a display module, a head-mounted display apparatus, a display, a mobile phone, a tablet computer, an intelligent interactive terminal, etc.

The display type of the display apparatus is, for example, organic light-emitting diode display or quantum dot light-emitting diode display.

The display apparatus shown in FIG. 7 includes a polarizer 100 covering the packaging cover plate 2, and a protective cover plate 200 covering the polarizer 100.

In some embodiments, a material of the protective cover plate 200 includes glass.

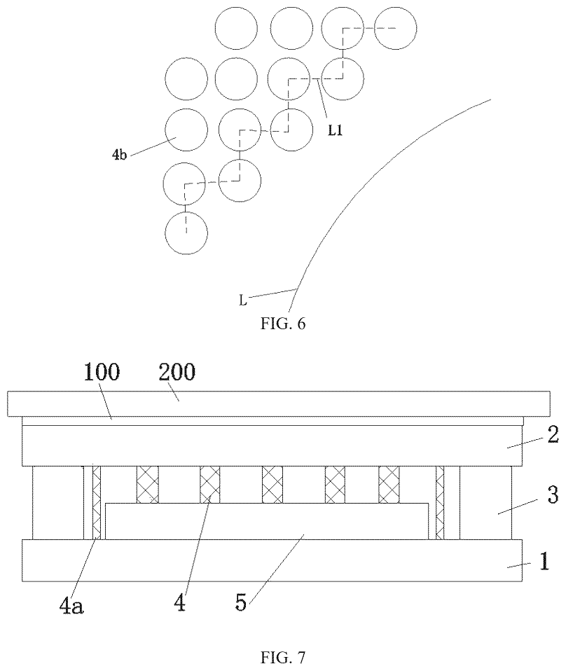

With continued reference to FIG. 5 and FIG. 6 and in combination with FIG. 1 and FIG. 2, an embodiment of the present disclosure also provides a display motherboard, including:

a plurality of display panels, where the display panel includes: a display substrate 1 including a display region 1a and a peripheral region 1b, a plurality of light-emitting elements disposed on the surface of one side of the display region 1a of the display substrate 1, a packaging cover plate 2 disposed on one side of the light-emitting elements away from the display substrate 1, and a packaging structure 3 disposed on the surface of one side of the peripheral region 1b of the display substrate 1, and the packaging structure 3 is disposed between the display substrate 1 and the packaging cover plate 2 and surrounds the plurality of light-emitting elements; and

a plurality of dummy support pillars 4b disposed outside an outer boundary of the display panel, where the distance d between orthographic projections of the dummy support pillars 4b on the plane where the display motherboard is disposed and an orthographic projection of the display panel on the plane where the display motherboard is disposed is greater than 600 um.

Inventors of the present disclosure have found that when the distance d between the dummy support pillars 4b and the cutting line L is too small, the surface of the display panel has a great gradient among positions of the dummy support pillars 4b and the position of the cutting line L, and a black edge defect easily occurs during cutting of a cutter wheel When the height of the packaging structure 3 is not matched with the distance between the display substrate 1 and the packaging cover plate 2, an edge ring halo defect (Newton ring) is also easy to occur. When the distance between the dummy support pillars 4b and the cutting line L is large enough, the defects of black edge and Newton ring are obviously improved. 600 um is the lower limit of the safe distance between the dummy support pillars 4b and the cutting line L.

In some embodiments, a cross section of the dummy support pillar 4b is circular. The dummy support pillars 4b are separated from the display panel after a cutting process.

In some embodiments, the outer boundary of the display panel includes a smooth curve segment, the plurality of dummy support pillars 4b are arranged in rows and columns (the row and column arrangement here may mean that the plurality of dummy support pillars 4b are arranged in a plurality of rows and a plurality of columns), and the central connecting line of the plurality of dummy support pillars 4b facing one side of the smooth curve segment of the display panel is stepped, so that the number of the dummy support pillars 4b is as large as possible in an allowable space.

The display panel is, for example, a circle or rounded angle polygon. The display apparatus according to the embodiment of the present disclosure may include various smart wearable devices such as a smart watch. When the display panel is a circle or rounded angle polygon, the aesthetic degree of the smart wearable device can be improved and user experience is improved.

In some embodiments, the materials of the support pillars 4, the auxiliary support pillars 4a and the dummy support pillars 4b all include polyimide.

It should be noted that the features according to the above respective embodiments may be combined appropriately.

The various embodiments in the present disclosure are described in a progressive manner, the same or similar parts between the various embodiments may be referred to each other, and each embodiment focuses on the differences from the other embodiments.

The scope of protection of the present disclosure is not limited to the above embodiments. Obviously, those skilled in the art can make various alterations and transformations to the present disclosure without departing from the scope and spirit of the present disclosure. It is intend that the present disclosure also includes such alterations and transformations provided that they fall within the scope of claims of the present disclosure and their technical equivalents.

It should be noted that in the accompanying drawings, for clarity of the illustration, the dimensions of the layers and regions may be scaled up. It may be understood that when an element or layer is described as being “above” another element or layer, the described element or layer may be directly on the other element or layer, or an intermediate layer may exist. In addition, it may be understood that when an element or layer is described as being “below” another element or layer, the described element or layer may be directly below the other element or layer, or more than one intermediate layer or element may exist. In addition, it may be further understood that when a layer or element is described as being arranged “between” two layers or elements, the described layer or element may be the only layer between the two layers or elements, or more than one intermediate layer or element may exist. In the whole description, like reference signs denote like elements

In the present disclosure, the terms “first”, “second” and “third” are used for descriptive purposes only and are not to be construed as indicating or implying relative importance. The term “plurality of” refers to two or more, unless specifically defined otherwise.

1. A display panel comprising:
a display substrate comprising a display region and a peripheral region;
a plurality of light-emitting elements disposed on a surface of one side of a display region of the display substrate;
a packaging cover plate disposed on one side of the plurality of light-emitting elements away from the display substrate;
a plurality of support pillars disposed between the display substrate and the packaging cover plate, wherein orthographic projections of the plurality of support pillars on the display substrate are disposed at gaps of orthographic projections of the plurality of light-emitting elements on the display substrate, an orthographic projection of each of the plurality of support pillars on the display substrate comprises a main body region and a plurality of branch regions connected with end parts of the main body region, the main body region and the plurality of branch regions are all disposed between adjacent light-emitting elements in the plurality of light-emitting elements, and there is an included angle greater than 0° and less than 180° between an extension direction of each of the plurality of branch regions and an extension direction of the main body region.

2. The display panel according to claim 1, wherein the plurality of light-emitting elements are arranged in a plurality of rows in a first direction, the plurality of light-emitting elements are arranged in a plurality of columns in a second direction, the first direction and the second direction are two directions parallel to a plane where the display substrate is disposed, and the first direction and the second direction intersect with each other; and
the main body region is a strip-shaped region extending in the second direction.

3. The display panel according to claim 2, wherein two light-emitting elements adjacent to one of the plurality of branch regions have at least one pair of parallel boundaries, the branch region is disposed between the pair of parallel boundaries, and an extension direction of the branch region is the same as an extension direction of the pair of parallel boundaries.

4. The display panel according to claim 3, wherein the plurality of support pillars in two adjacent rows of light-emitting elements are arranged in a staggered manner in the second direction.

5. The display panel according to claim 4, wherein at least part of light-emitting elements in the plurality of light-emitting elements are adjacent to the plurality of support pillars in the first direction, boundaries of the at least part of light-emitting elements are polygons, and the polygons comprise edges opposite the main body regions of the plurality of support pillars and edges opposite the plurality of branch regions of the plurality of support pillars; and
at least part of light-emitting elements in the plurality of light-emitting elements are adjacent to the plurality of support pillars in the second direction, boundaries of the part of light-emitting elements are polygons, and the polygons comprise edges opposite branch regions of adjacent support pillars.

6. The display panel according to claim 3, wherein the plurality of support pillars are distributed in alternate rows in the second direction, and the plurality of support pillars are arranged in a plurality of columns in the second direction;
one single light-emitting element is disposed between two adjacent support pillars in the first direction, a boundary of the single light-emitting element is a polygon, and the polygon comprises edges opposite branch regions of the two adjacent support pillars; and
one single light-emitting element is disposed between two adjacent support pillars in the second direction, and a boundary of the single light-emitting element comprises edges opposite branch regions of the two adjacent support pillars.

7. The display panel according to claim 1, wherein each of the plurality of branch regions is polygonal or smooth curved.

8. The display panel according to claim 1, wherein the display panel further comprises:
a packaging structure, wherein the packaging structure is disposed between the display substrate and the packaging cover plate, is disposed on a surface of one side of the peripheral region, and surrounds the plurality of light-emitting elements; and
auxiliary support pillars, wherein the auxiliary support pillars are disposed between the display substrate and the packaging cover plate, and are disposed between a region where the plurality of light-emitting elements are disposed and a region where the packaging structure is disposed.

9. The display panel according to claim 8, wherein the display substrate comprises a gate electrode driving circuit disposed in the peripheral region, and at least part of the auxiliary support pillars are disposed in a region where the gate electrode driving circuit of the display substrate is disposed.

10. The display panel according to claim 1, wherein the display panel further comprises a packaging structure, and the packaging structure is disposed between the display substrate and the packaging cover plate, is disposed on a surface of one side of the peripheral region and surrounds the plurality of light-emitting elements;
a segment of the display substrate covered by the packaging structure comprises a base, a conductive layer and an insulating layer which are sequentially laminated in a third direction, and the third direction is a direction where the display substrate points to the packaging cover plate; and
the conductive layer has a plurality of first openings, the insulating layer fills each of the plurality of first openings, the insulating layer has at least one second opening in a region where the plurality of first openings are disposed, there is a gap between the at least one second opening and an edge of the first opening where the at least one second opening is disposed, and the packaging structure fills the at least one second opening.

11. The display panel according to claim 10, wherein a plurality of packaging openings of the display substrate in a packaging region comprise packaging openings in at least one shape of a first polygon, a second polygon and a closed smooth curve shape, the packaging openings comprise the plurality of first openings and the at least one second opening, the first polygon is a polygon with obtuse vertex angles and the second polygon is a polygon with rounded vertex angles.

12. The display panel according to claim 1, wherein the display panel further comprises a packaging structure, and the packaging structure is disposed between the display substrate and the packaging cover plate, is disposed on a surface of one side of the peripheral region and surrounds the plurality of light-emitting elements;
the surface of one side of the display substrate facing the packaging cover plate has a plurality of grooves in a coverage region of the packaging structure, and the packaging structure fills the plurality of grooves; and
the plurality of grooves comprise grooves in at least one shape of a first polygon, a second polygon and a closed smooth curve shape, the first polygon is a polygon with obtuse vertex angles, and the second polygon is a polygon with rounded vertex angles.

13. The display panel according to claim 12, wherein a material of the grooves comprises an insulating material;
the display substrate further comprises the conductive layer with a plurality of opening regions, the display panel further comprises an insulating layer, the insulating layer fills the opening regions of the conductive layer, the grooves are aggregated into a plurality of groove clusters, the plurality of groove clusters are in a one-to-one correspondence with the plurality of opening regions in the conductive layer, and grooves in the groove clusters are disposed in corresponding opening regions of the conductive layer; and
the plurality of opening regions comprise opening regions in at least one shape of a first polygon, a second polygon and a closed smooth curve shape, the first polygon is a polygon with obtuse vertex angles, and the second polygon is a polygon with rounded vertex angles.

14. A display panel comprising:
a display substrate comprising a display region and a peripheral region;
a plurality of light-emitting elements disposed on a surface of one side of a display region of the display substrate, wherein the plurality of light-emitting elements are arranged in a plurality of rows in a first direction, the plurality of light-emitting elements are arranged in a plurality of columns in a second direction, the first direction and the second direction are two directions parallel to the plane where the display substrate is disposed, and the first direction and the second direction intersect with each other;
a packaging cover plate disposed on one side of the plurality of light-emitting elements away from the display substrate; and
a plurality of support pillars, wherein the plurality of support pillars are disposed between the display substrate and the packaging cover plate, and the plurality of support pillars and the plurality of light-emitting elements in the second light-emitting element columns are alternately arranged in the second direction; and
wherein the plurality of columns of light-emitting elements are divided into first light-emitting element columns and second light-emitting element columns, which are alternately arranged in the first direction, a number of the plurality of light-emitting elements in each first light-emitting element column is equal, a number of the plurality of light-emitting elements in each second light-emitting element column is equal, the number of the plurality of light-emitting elements in the first light-emitting element column is twice the number of the plurality of light-emitting elements in the second light-emitting element column, and the plurality of light-emitting elements in the first light-emitting element column and the plurality of light-emitting elements in the second light-emitting element column are arranged in a staggered manner in the second direction.

15. The display panel according to claim 14, wherein a boundary of each of the plurality of light-emitting elements in the second light-emitting element column is a rectangle with at least part of a region of a long edge on one side being recessed, and long edges of the rectangle extend in the second direction; and
an opening area of each of the plurality of light-emitting elements in the second light-emitting element column is greater than an opening area of each of the plurality of light-emitting elements in the first light-emitting element column.

16. The display panel according to claim 14, further comprising:
a packaging structure, wherein the packaging structure is disposed on a surface of one side of the peripheral region of the display substrate, is disposed between the display substrate and the packaging cover plate, and surrounds the plurality of light-emitting elements; and
auxiliary support pillars, wherein the auxiliary support pillars are disposed between the display substrate and the packaging cover plate, are disposed between a region where the plurality of light-emitting elements are disposed and a region where the packaging structure is disposed.

17. The display panel according to claim 14, wherein the display panel further comprises a packaging structure, and the packaging structure is disposed between the display substrate and the packaging cover plate, is disposed on a surface of one side of the peripheral region and surrounds the plurality of light-emitting elements;
a segment of the display substrate covered by the packaging structure comprises a base, a conductive layer and an insulating layer which are sequentially laminated in a third direction, and the third direction is a direction where the display substrate points to the packaging cover plate; and
the conductive layer has a plurality of first openings, the insulating layer fills each of the plurality of first openings, the insulating layer has at least one second opening in a region where the plurality of first openings are disposed, there is a gap between the at least one second opening and an edge of the first opening where the at least one second opening is disposed, and the packaging structure fills the at least one second opening; a plurality of packaging openings of the display substrate in a packaging region comprise packaging openings in at least one shape of a first polygon, a second polygon and a closed smooth curve shape, the packaging openings comprise the plurality of first openings and the at least one second openings, the first polygon is a polygon with obtuse vertex angles, and the second polygon is a polygon with rounded vertex angles.

18. The display panel according to claim 14, wherein the display panel further comprises a packaging structure, and the packaging structure is disposed between the display substrate and the packaging cover plate, is disposed on a surface of one side of the peripheral region, and surrounds the plurality of light-emitting elements; and
the surface of one side of the display substrate facing the packaging cover plate has a plurality of grooves in a coverage region of the packaging structure, and the packaging structure fills the plurality of grooves; the plurality of grooves comprise grooves in at least one shape of a first polygon, a second polygon and a closed smooth curve shape, the first polygon is a polygon with obtuse vertex angles, and the second polygon is a polygon with rounded vertex angles.

19. A display motherboard comprising:
a plurality of display panels, wherein the display panel comprises a display substrate comprising a display region and a peripheral region, a plurality of light-emitting elements disposed on a surface of one side of a display region of the display substrate, a packaging cover plate disposed on one side of the plurality of light-emitting elements away from the display substrate, and a packaging structure disposed on a surface of one side of the peripheral region of the display substrate, wherein the packaging structure is disposed between the display substrate and the packaging cover plate and surrounds the plurality of light-emitting elements; and
a plurality of dummy support pillars disposed outside an outer boundary of the display panel, wherein a distance between orthographic projections of the plurality of dummy support pillars on a plane where the display motherboard is disposed and an orthographic projection of the display panel on the plane where the display motherboard is disposed is greater than 600 microns.

20. The display motherboard according to claim 19, wherein a cross section of each of the plurality of dummy support pillars is circular; and/or,
the outer boundary of the display panel comprises a smooth curve segment, the plurality of dummy support pillars are arranged in rows and columns, and a central connecting line of the plurality of dummy support pillars facing one side of the smooth curve segment of the display panel is stepped.
